(19) United States
(12) Patent Application Publication
(10) Pub. No.: US 2020/0300915 A1
(43) Pub. Date: Sep. 24, 2020

(54) SEMICONDUCTOR DEVICE, METHOD FOR DIAGNOSING SEMICONDUCTOR DEVICE, AND DIAGNOSIS PROGRAM FOR SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Tomohiro TACHIKAWA, Setagaya Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 16/572,671

(22) Filed: Sep. 17, 2019

(30) Foreign Application Priority Data
Mar. 20, 2019 (JP) 2019-053649

(51) Int. Cl. G01R 31/3185; G01R 31/317

(52) U.S. Cl. CPC G01R 31/318583; G01R 31/318525; G01R 31/318544; G01R 31/31703

(57) ABSTRACT

A semiconductor device of an embodiment includes a main circuit, a monitoring circuit, a comparator, and a DFT control circuit. The monitoring circuit includes a same circuit configuration as a circuit configuration of the main circuit. The comparator compares an output of the main circuit and an output of the monitoring circuit. The DFT control circuit inverts a value of at least one flipflop, among values of a plurality of flipflops provided in the main circuit, and sets the inverted value to at least one flipflop via a scan chain.

### CROSS-REFERENCE TO RELATED APPLICATIONS

This application is based upon and claims the benefit of priority from the prior Japanese Patent Application No. 2019-053649 filed on Mar. 20, 2019; the entire contents of which are incorporated herein by reference.

### FIELD

An embodiment of the present invention relates to a semiconductor device, a method for diagnosing a semiconductor device, and a diagnosis program for a semiconductor device.

### BACKGROUND

For the purpose of functional safety standards for automobiles, demand for a semiconductor device loaded with a failure detection circuit is increasing. A system loaded with a semiconductor device like this includes hardware that detects a failure, and software that executes various kinds of processing in accordance with a kind or the like of the detected failure.

However, whether the hardware and the software are functioning normally cannot usually be verified unless a failure actually occurs in the semiconductor. Therefore, it is difficult to diagnose whether the hardware and the software as functional safety mechanisms for a semiconductor device are operating normally.

Therefore, there is known a method of diagnosing whether or not a simulated failure can be detected as a failure by causing a semiconductor device to generate the simulated failure forcibly. As the method of diagnosing the functional safety mechanism by injecting a simulated failure to the semiconductor device, there is a method of providing a plurality of test points including a flipflops for test point, and injecting a simulated failure.

However, it is known that a circuit that can be activated in the test point is only a part of the entire circuit (more specifically, approximately 2% of the entire circuit). Consequently, the method of injecting a simulated failure from the test point has a problem that only a limited circuit portion can be caused to generate the simulated failure.

### BRIEF DESCRIPTION OF THE DRAWINGS

FIG. 1 is a block diagram illustrating one example of a configuration of a semiconductor device according to one embodiment;

FIG. 2 is a block diagram illustrating an example of a detailed internal configuration of a failure detection circuit module;

FIG. 3A is a diagram illustrating an example of a value of a RAM before simulated failure injection;

FIG. 3B is a diagram illustrating an example of a value of the RAM after simulated failure injection; and

FIG. 4 is a flowchart illustrating an example of a flow of failure detection diagnosis processing by a simulated failure.

### DETAILED DESCRIPTION

A semiconductor device of an embodiment includes a main circuit, a monitoring circuit, a comparator, and a DFT control circuit. The monitoring circuit includes a same circuit configuration as a circuit configuration of the main circuit. The comparator compares an output of the main circuit and an output of the monitoring circuit. The DFT control circuit inverts a value of at least one flipflop among values of a plurality of flipflops that are provided in the main circuit, and sets the inverted value to at least one flipflop via a scan chain.

Hereinafter, the embodiment will be described in detail with reference to the drawings.

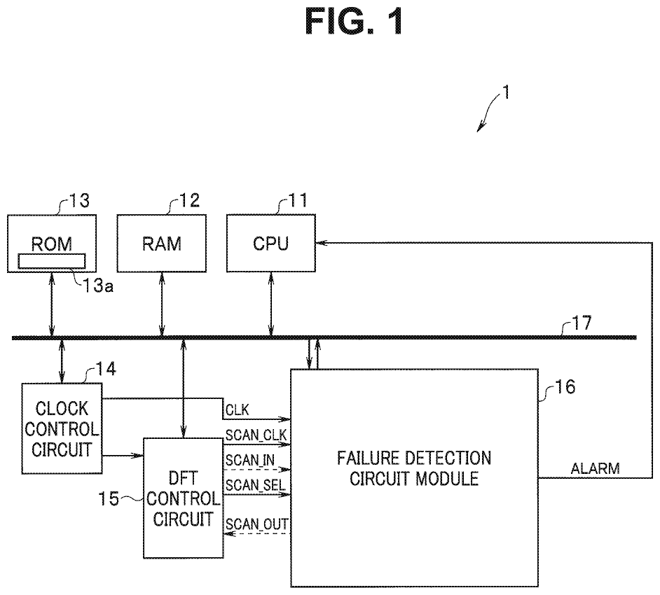

First, based on FIG. 1, a configuration of a semiconductor device according to one embodiment will be described.

FIG. 1 is a block diagram illustrating an example of the configuration of the semiconductor device according to one embodiment.

A semiconductor device 1 of the present embodiment is configured to include a central processing unit (hereinafter, referred to as a CPU) 11, a RAM 12, a ROM 13, a clock control circuit 14, a DFT (design for test) control circuit 15, a failure detection circuit module 16, and a bus 17. The CPU 11, the RAM 12, the ROM 13, the clock control circuit 14, the DFT control circuit 15, and the failure detection circuit module 16 are connected to one another via the bus 17.

The CPU 11 is a control circuit that controls the respective circuits in the semiconductor device 1. The CPU 11 reads various operation programs that are stored in the RAM 12, expands the operation programs on the ROM 13, executes the operation programs, and thereby controls the respective circuits in the semiconductor device 1. In particular, the CPU 11 can execute failure diagnosis processing that will be described later by expanding a diagnosis program 13a stored in the ROM 13 on the RAM 12 and executing the diagnosis program 13a.

The clock control circuit 14 generates a clock for normal operation (hereinafter, simply referred to as a normal clock), and outputs the clock for normal operation to the DFT control circuit 15 and the failure detection circuit module 16. Further, the clock control circuit 14 controls supply of the normal clock to the failure detection circuit module 16, and stop of supply of the normal clock.

The DFT control circuit 15 outputs a clock for scan test (hereinafter, simply referred to as a scan clock) that shifts a value with the scan chain, scan-in that inputs a value for scan test to the scan chain, and a scan selection signal that switches a normal operation and a scan operation to the failure detection circuit module 16. Further, scan-out that is outputted from the scan chain is inputted to the DFT control circuit 15.

The failure detection circuit module 16 outputs a failure detection alarm signal to the CPU 11 when detecting a failure. The CPU 11 executes processing corresponding to a kind of the failure based on the failure detection alarm signal. Note that in FIG. 1 the failure detection circuit module 16 is configured to output the failure detection alarm signal to the CPU 11, but the failure detection circuit module 16 may output the failure detection alarm signal to the CPU 11.

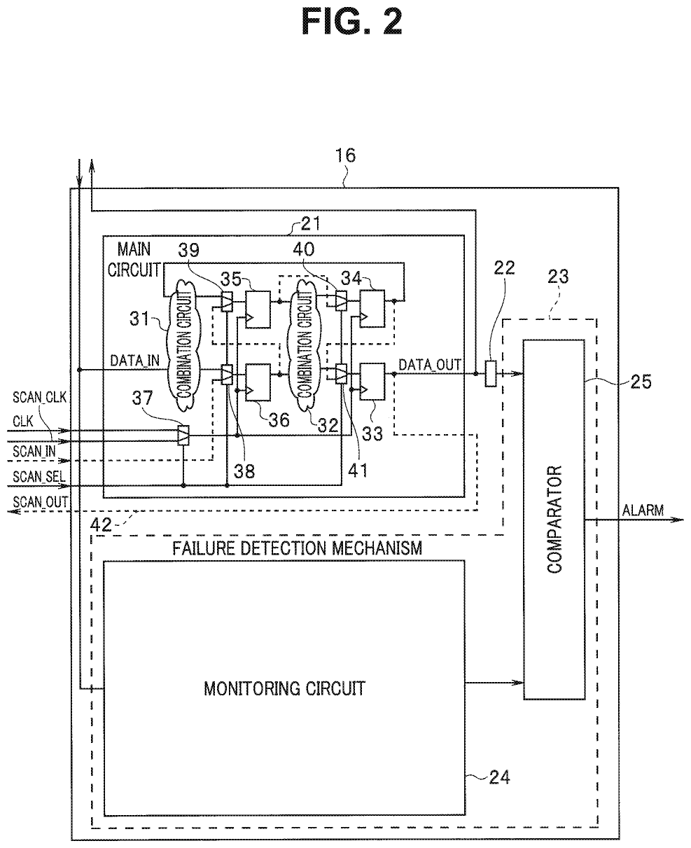

FIG. 2 is a block diagram illustrating an example of a detailed internal configuration of the failure detection circuit module.

As illustrated in FIG. 2, the failure detection circuit module 16 is configured to have a main circuit 21, an isolation element 22, and a failure detection mechanism 23. The failure detection mechanism 23 is configured by a monitoring circuit 24, and a comparator 25.

The main circuit 21 is configured to include combination circuits 31 and 32, flipflops (hereinafter, referred to as FF) 33, 34, 35 and 36, and scan selectors 37, 38, 39, 40 and 41. Further, the monitoring circuit 24 has a same circuit configuration as the circuit configuration of the main circuit 21.

The main circuit 21 and the monitoring circuit 24 receive same input signals (DATA_IN) via the bus 17. An output signal (DATA_OUT) of the main circuit 21 is outputted to the bus 17, and is inputted to the isolation element 22. An output signal of the monitoring circuit 24 is inputted to the comparator 25.

The isolation element 22 can mask the output signal of the main circuit 21. When the mask is cancelled by the isolation element 22, the output signal of the main circuit 21 is inputted to the comparator 25.

The comparator 25 compares the output signal of the main circuit 21 and the output signal of the monitoring circuit 24, and when the output signals do not correspond to each other, the comparator 25 outputs a failure detection alarm signal to the CPU 11.

The scan selector 37 is a selector that switches a normal clock (CLK), and a scan clock (SCAN_CLK) and outputs the normal clock (CLK) or the scan clock (SCAN_CLK), based on a scan selection signal (SCAN_SEL). In other words, in the present embodiment, a normal operation mode and a scan operation mode are switched based on the scan selection signal. By switching to the scan operation mode, a scan chain 42 is configured.

The normal clock or the scan clock that is selected by the scan selector 37 is inputted to the FFs 33 to 36. The scan selectors 38 to 41 are selectors that switch an input from the normal circuit and an input from the scan chain 42 based on the scan selection signal, and output the input from the normal circuit or the input from the scan chain 42 to the FF 33 to 36.

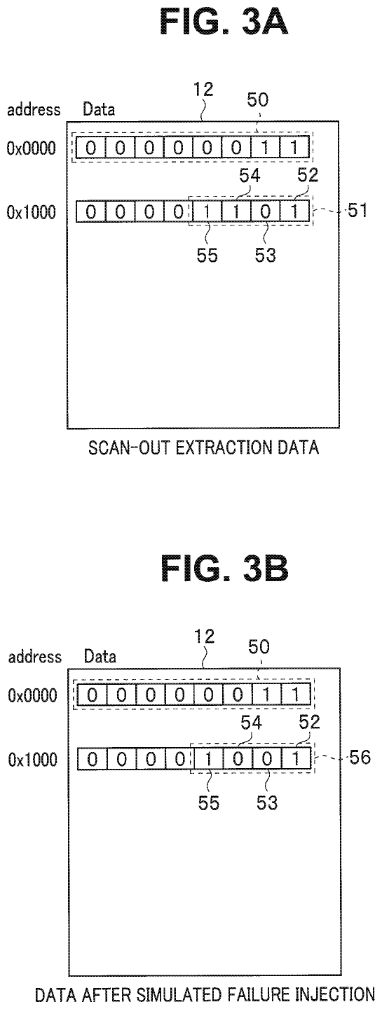

Here, processing of failure injection will be described by using FIGS. 3A and 3B.

FIG. 3A is a diagram illustrating an example of a value of the RAM before simulated failure injection, and FIG. 3B is a diagram illustrating an example of a value of the RAM after simulated failure injection.

A value of an address “0x0000” in FIG. 3A is simulated failure FF information 50 indicating a position of an FF where a simulated failure is caused to occur.

In the present embodiment, the normal clock is stopped during a normal operation, and the scan selection signal is enabled, whereby an operation mode is switched to the scan operation mode. Thereby, data (bit value) retained in the FFs 33 to 36 during the normal operation is shifted out via the scan chain 42.

A value of an address “0x1000” in FIG. 3A shows scan-out data 51 that is shifted out with the scan chain 42. In the scan-out data 51, a value 52 indicates a bit value of the FF 33, a value 53 indicates a bit value of the FF 34, a value 54 indicates a bit value of the FF 35, and a value 55 indicates a bit value of the FF 36.

The CPU 11 refers to the simulated failure FF information 50, and injects a simulated failure. More specifically, the simulated failure FF information 50 indicates “11”, so that the simulated failure is injected to a third FF. In the present embodiment, a first FF, a second FF and the like are determined in order from an FF closest to scan-out. In other words, in the present embodiment, the FF 33 is the first FF, the FF 34 is the second FF, the FF 35 is the third FF, and the FF 36 is a fourth FF.

The CPU 11 refers to the simulated failure FF information 50, reads the value 54 of the FF 35 which is the third FF, and inverts the value and writes the value to an original position. In other words, the value 54 of the FF 35 is “1”, so that the CPU 11 inverts the value and writes “0” to the original position. Thereby, as illustrated in FIG. 3B, in the RAM 12 after simulated failure injection, the value 54 of the third FF 35 is “0”.

A value of an address “0x1000” in FIG. 3B indicates scan-in data 56 for shifting in with the scan chain 42. The scan-in data 56 is inputted via the scan chain 42, is subjected to scan shift, and thereby is set to the FF 33, the FF 34, the FF 35, and the FF 36.

In other words, “1” that is a bit value of the value 52 is set to the FF 33, “0” that is a bit value of the value 53 is set to the FF 34, “0” that is a bit value of the value 54 is set to the FF 35, and “1” that is a bit value of the value 55 is set to the FF 36. Thereby, the inverted value is set to the FF 35 which is third closest to scan-out, and a simulated failure is injected to the FF 35.

Next, the failure detection diagnosis processing of the semiconductor device 1 configured in this way will be described.

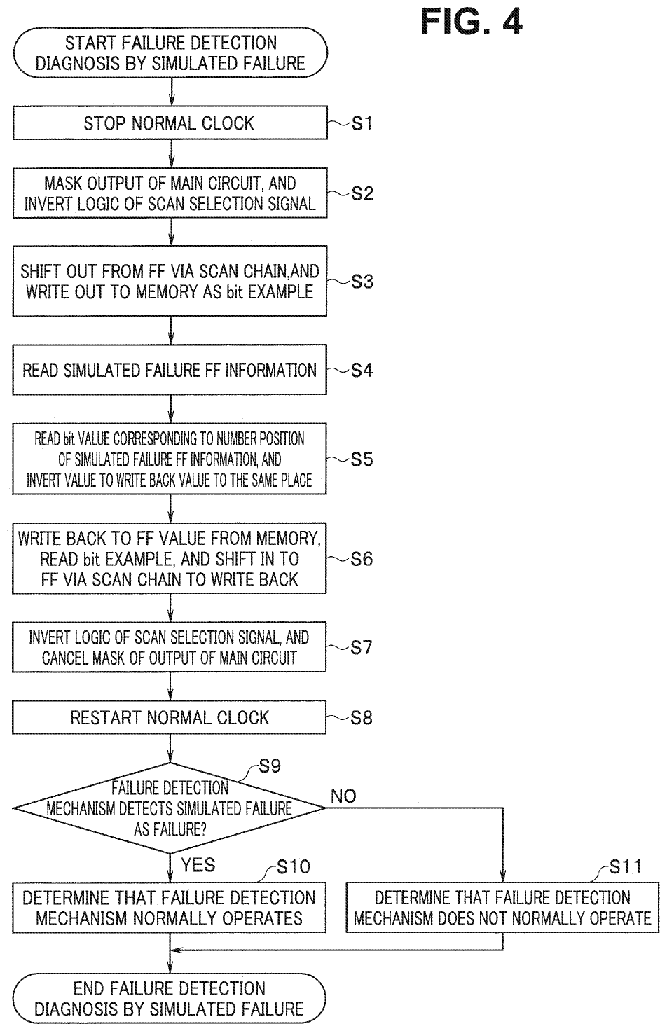

FIG. 4 is a flowchart illustrating an example of a flow of the failure detection diagnosis processing by a simulated failure.

Note that the processing in FIG. 4 is carried out by the CPU 11 expanding the diagnosis program stored in the ROM 13, on the RAM 12.

First, the CPU 11 controls the clock control circuit 14, and stops the normal clock which is inputted to the failure detection circuit module 16 (S1).

Next, the CPU 11 controls the DFT control circuit 15, masks the output of the main circuit 21 by the isolation element 22, and changes a logic of the scan selection signal (S2). Thereby, the outputs of the scan selectors 37, 38, 39, 40, and 41 of the main circuit 21 in the failure detection circuit module 16 are switched to a scan chain 42 side from a normal side, and the clock which is inputted to the FF 33 to 36 is switched to the scan clock from the normal clock.

Next, the CPU 11 controls the DFT control circuit 15, and stores the values which are read from the FF 33 to FF 36 with the scan chain 42 in the RAM 12 as the scan-out data 51 (S3). Thereby, as illustrated in FIG. 3A, the bit values which are read from the FF 33 to FF 36 are stored in the RAM 12 as the scan-out data 51.

Next, the CPU 11 reads the simulated failure FF information 50 which is stored in the RAM 12 in advance (S4). The simulated failure FF information 50 may be obtained by a method of causing the ROM 13 to store a value indicating the FF which is easily failed in advance, and reading the value stored in the ROM 13 to cause the RAM 12 to store the value, or may be changed to a value indicating another FF in accordance with an operating state, a number of times of diagnosis and the like of the semiconductor device 1. In other words, the simulated failure FF information 50 which is stored in the RAM 12 is rewritable by the user. In the present embodiment, as illustrated in FIG. 3A, the simulated failure FF information 50 indicating the third closest FF 35 to scan-out is stored in the RAM 12.

Next, the CPU 11 creates the scan-in data 56 for scan-in which is inputted to scan-in. More specifically, the CPU 11 reads the bit value corresponding to a number position of the simulated failure FF information 50, and inverts the value and writes back the value to a same plate (S5). Thereby, as illustrated in FIG. 3B, the scan-in data 56 in which the bit value of the value 54 (the value of the FF 35) corresponding to the number position of the simulated failure FF information 50 is rewritten to 0 from 1 is created.

Next, the CPU 11 reads the scan-in data 56 from the RAM 12, shifts in the FF 33 to FF 36 via the scan chain 42, and sets the value to the FF 33 to FF 36 (S6).

Next, the CPU 11 changes the logic of the scan selection signal, and cancels the mask for the output of the main circuit 21 by the isolation element 22 (S7). Subsequently, the CPU 11 controls the clock control circuit 14, and causes the clock control circuit 14 to restart the normal clock (S8). Thereby, the output from the main circuit 21, in other words, the output in which the simulated failure is injected is inputted to the comparator 25.

Next, the CPU 11 determines whether or not the failure detection mechanism 23 detects the simulated failure as a failure (S9). More specifically, the CPU 11 determines whether or not the failure detection mechanism 23 detects the simulated failure as a failure based on whether or not the failure detection alarm signal is outputted from the comparator 25. As described above, the bit value of the FF 35 corresponding to the number position of the simulated failure FF information 50 is rewritten to 0 from 1, and thereafter is set to the FF 35, so that the outputs of the main circuit 21 and the monitoring circuit 24 do not correspond to each other. Therefore, when the failure detection mechanism 23 is operating normally, the failure detection alarm signal is outputted to the CPU 11 from the comparator 25.

When the failure detection alarm signal is outputted from the comparator 25, that is, when the simulated failure is detected as a failure (S9: YES), the CPU 11 determines that the failure detection mechanism 23 is operating normally (S10), and ends the processing of failure detection diagnosis by the simulated failure. Note that when the simulated failure is detected, the CPU 11 executes software processing corresponding to the failure, and verifies whether the software processing has been correctly executed.

When the failure detection alarm signal is not outputted from the comparator 25, that is, when the simulated failure is not detected as a failure (S9: NO), the CPU 11 determines that the failure detection mechanism 23 is not operating normally (S11), and ends the processing of the failure detection diagnosis.

As above, the values of the FF 33 to the FF 36 in the main circuit 21 are scanned out by using the scan chain 42 of the main circuit 21, and are stored in the RAM 12. At least one of the stored values of the FF 33 to the FF 36 is inverted, and thereafter is scanned in the FF 33 to the FF 36 in the main circuit 21 by using the scan chain 42, whereby the simulated failure is injected to an arbitrary FF.

Note that in the present embodiment, after the values of the FF 33 to the FF 36 in the main circuit 21 are scanned out by using the scan chain 42 and are stored in the RAM 12, at least one value is inverted, and is scanned in the FF 33 to the FF 36 in the main circuit 21 by using the scan chain 42, but the present invention is not limited to this. For example, when the values (internal states) of the FF 33 to the FF 36 are known in advance, a value of at least one FF among the values of the FF 33 to the FF 36, is inverted, and the inverted value may be set to at least one FF via the scan chain 42.

In general, in a large-scale semiconductor device, the DFT circuit is incorporated so that all the FFs in the circuit are scannable so that a scan test can be executed, and therefore, a simulated failure can be injected to an arbitrary FF by using the existing DFT circuit.

Consequently, according to the semiconductor device of the present embodiment, diagnosis by injection of the simulated failure to the logic circuit can be carried out without adding a new circuit.

Note that as for the respective steps in the flowchart in the present description, an execution order may be changed, a plurality of steps may be simultaneously executed, or the respective steps may be executed in a different order at each execution, within the range without departing from the gist of the present invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device, comprising:
a main circuit;
a monitoring circuit including a same circuit configuration as a circuit configuration of the main circuit;
a comparator configured to compare an output of the main circuit and an output of the monitoring circuit; and
a DFT control circuit configured to invert a value of at least one flipflop among values of a plurality of flipflops provided in the main circuit, and set the inverted value to the at least one flipflop via a scan chain.

2. The semiconductor device according to claim 1,
wherein the DFT control circuit scans out the values of the plurality of flipflops via the scan chain and stores the values in a storage section,
the semiconductor device further comprising a control circuit configured to invert at least one value of the values of the plurality of flipflops stored in the storage section, and store the value in the storage section, and
the DFT control circuit scans in the value stored in the storage section by the control circuit via the scan chain, and sets the value to the plurality of flipflops.

3. The semiconductor device according to claim 2,
wherein the control circuit inverts the at least one value, based on simulated failure information stored in the storage section.

4. The semiconductor device according to claim 3,
wherein the simulated failure information is information indicating a position of a flipflop to which a simulated failure is injected, among the plurality of flipflops.

5. The semiconductor device according to claim 1, comprising:
a clock control circuit configured to control supply of a normal clock to the main circuit and stop of supply of the normal clock.

6. The semiconductor device according to claim 1, comprising:
a mask circuit configured to mask the output of the main circuit.

7. A method for diagnosing a semiconductor device,
the semiconductor device including a main circuit including a desired circuit configuration, a monitoring circuit including a same circuit configuration as a circuit configuration of the main circuit, and a comparator configured to compare an output of the main circuit and an output of the monitoring circuit, the method comprising:
inverting a value of at least one flipflop, among values of a plurality of flipflops provided in the main circuit; and
setting the inverted value to the at least one flipflop via a scan chain.

8. The method for diagnosing a semiconductor device according to claim 7, comprising:
scanning out the values of the plurality of flipflops via the scan chain and storing the values in a storage section;
inverting at least one value of the values of the plurality of flipflops stored in the storage section and storing the value in the storage section; and
scanning in the value stored in the storage section via the scan chain and setting the value to the plurality of flipflops.

9. A computer-readable non-transitory recording medium recording a diagnosis program for a semiconductor device, comprising:
a step of inverting a value of at least one flipflop, among values of a plurality of flipflops provided in a main circuit and setting the inverted value to the at least one flipflop via a scan chain.

10. The computer-readable non-transitory recording medium recording a diagnosis program for a semiconductor device according to claim 9, comprising:
a step of scanning out the values of the plurality of flipflops via the scan chain and storing the values in a storage section;
a step of inverting at least one value of the values of the plurality of flipflops stored in the storage section and storing the inverted value in the storage section; and
a step of scanning in the value stared in the storage section via the scan chain and setting the value to the plurality of flipflops.
